(19) United States
(12) Patent Application Publication
(10) Pub. No.: US 2021/0358977 A1
(43) Pub. Date: Nov. 18, 2021

(54) ARRAY SUBSTRATE, MANUFACTURING METHOD THEREOF, AND CORRESPONDING DISPLAY DEVICE

(71) Applicants: Ordos Yuansheng Optoelectronics Co., Ltd., Ordos, Inner Mongolia (CN); BOE Technology Group Co., Ltd., Beijing (CN)

(72) Inventor: Yongqiang ZHANG, Beijing (CN)

(21) Appl. No.: 16/335,878

(22) PCT Filed: Oct. 15, 2018
(86) PCT No.: PCT/CN2018/110181

§ 371 Date: Mar. 22, 2019

(30) Foreign Application Priority Data
Feb. 1, 2018 (CN) 201810102322.5

(51) Int. Cl. H01L 27/12

(52) U.S. Cl. CPC H01L 27/1251; H01L 27/127; H01L 27/124

(57) ABSTRACT

The present disclosure relates to the field of display technologies, and embodiments provide an array substrate, a manufacturing method thereof and a corresponding display device. The array substrate includes a display region and a non-display region, and further includes a first thin film transistor in the display region and a second thin film transistor in the non-display region. A size of the second thin film transistor is smaller than that of the first thin film transistor, and a leakage current of the first thin film transistor is smaller than that of the second thin film transistor.

### RELATED APPLICATION(S)

The present application claims the benefit of Chinese Patent Application No. 201810102322.5 filed on Feb. 1, 2018, the entire disclosure of which is incorporated herein by reference.

### FIELD

The present disclosure relates to the field of display technologies, and is specifically directed to an array substrate, a manufacturing method thereof, and a corresponding display device.

### BACKGROUND

Among conventional display devices, both a liquid crystal display (LCD) and an organic electroluminescent display (OLED) are typically provided with a thin film transistor (TFT), wherein performances of the thin film transistor affect greatly performances of the display device.

In a display device, the thin film transistor may be disposed in a display region for controlling display of pixels. Of course, alternatively, the thin film transistor may also be disposed in a non-display region, for example, in a region where a Gate On Array (GOA) is located, as a part of the driving circuit. Among all available thin film transistors, a low temperature polysilicon (LTPS) thin film transistor and an oxide semiconductor thin film transistor have been widely used due to their high mobility.

### SUMMARY

According to an aspect of the present disclosure, an embodiment provides an array substrate comprising a display region and a non-display region. Further, the array substrate further comprises a first thin film transistor located in the display region and a second thin film transistor located in the non-display region, wherein a size of the second thin film transistor is smaller than a size of the first thin film transistor, and a leakage current of the first thin film transistor is smaller than a leakage current of the second thin film transistor.

According to some embodiments, in the array substrate provided by an embodiment of the present disclosure, the first thin film transistor comprises a first active layer made of an oxide semiconductor; and the second thin film transistor comprises a second active layer made of polysilicon.

According to some embodiments, the array substrate provided by an embodiment of the present disclosure further comprises: a base substrate; and a second active layer, a first insulating layer, a first conductive layer, a second insulating layer, a first active layer, and a second conductive layer disposed on the base substrate successively. Specifically, the first conductive layer comprises a first gate located in the display region and a second gate located in the non-display region; the second conductive layer comprises a first source and a first drain located in the display region, and a second source and a second drain located in the non-display region; the first active layer is in contact with both the first source and the first drain; and the second active layer is electrically connected to the second source and the second drain through via holes penetrating through the first insulating layer and the second insulating layer. In this case, the first gate, the second insulating layer, the first active layer, the first source, and the first drain constitute the first thin film transistor; and the second active layer, the first insulating layer, the second gate, the second insulating layer, the second source, and the second drain constitute the second thin film transistor.

According to some embodiments, the array substrate provided by an embodiment of the present disclosure further comprises: an etch barrier pattern disposed on a surface of the first active layer away from the second insulating layer.

According to some embodiments, the array substrate provided by an embodiment of the present disclosure further comprises: a touch signal line and a touch electrode located in the display region, wherein the touch signal line is electrically connected to the touch electrode, and the touch electrode is also used as a common electrode.

According to some embodiments, in the array substrate provided by an embodiment of the present disclosure, the touch signal line is formed in a same layer and of a same material as the first source and the first drain of the first thin film transistor. In addition, the array substrate further comprises: a third insulating layer disposed on a surface of the first thin film transistor away from the second insulating layer, wherein the touch electrode is located on a surface of the third insulating layer away from the thin film transistor, and is electrically connected to the touch signal line through a via hole penetrating through the third insulating layer.

According to some embodiments, the array substrate provided by an embodiment of the present disclosure further comprises: a third insulating layer and a fourth insulating layer disposed successively on a surface of the first thin film transistor away from the second insulating layer. Further, a touch signal line is located between the third insulating layer and the fourth insulating layer. In addition, a touch electrode is located on a surface of the fourth insulating layer away from the third insulating layer, and is electrically connected to the touch signal line through a via hole penetrating through the fourth insulating layer.

According to some embodiments, the array substrate provided by an embodiment of the present disclosure further comprises: a data line located in a different layer from the touch signal line and parallel to the touch signal line, wherein an orthographic projection of the touch signal line on the base substrate and an orthographic projection of the data line on the base substrate at least partially overlap with each other.

According to another aspect of the present disclosure, there is further provided a display device. The display device comprises the array substrate as described in any of the foregoing embodiments.

According to a further aspect of the present disclosure, there is further provided a manufacturing method for an array substrate. Specifically, the manufacturing method comprises steps of: providing a base substrate, the base substrate comprising a display region and a non-display region; forming, on the base substrate, a first thin film transistor located in the display region and a second thin film transistor located in the non-display region, wherein a size of the second thin film transistor is smaller than a size of the first thin film transistor, and a leakage current of the first thin film transistor is smaller than a leakage current of the second thin film transistor.

According to some embodiments, in the manufacturing method for an array substrate as provided by an embodiment of the present disclosure, the first thin film transistor comprises a first active layer made of an oxide semiconductor, and the second thin film transistor comprises a second active layer made of polysilicon.

According to some embodiments, in the manufacturing method for an array substrate as provided by an embodiment of the present disclosure, the step of forming, on the base substrate, a first thin film transistor located in the display region and a second thin film transistor located in the non-display region comprises: forming, on the base substrate, a second active layer, a first insulating layer, a first conductive layer, a second insulating layer, a first active layer, and a second conductive layer successively. Specifically, the first conductive layer comprises a first gate located in the display region and a second gate located in the non-display region; the second conductive layer comprises a first source and a first drain located in the display region, and a second source and a second drain located in the non-display region; the first active layer is in contact with both the first source and the first drain; and the second active layer is electrically connected to the second source and the second drain through via holes penetrating through the first insulating layer and the second insulating layer. Further, the first gate, the second insulating layer, the first active layer, the first source, and the first drain constitute the first thin film transistor; and the second active layer, the first insulating layer, the second gate, the second insulating layer, the second source, and the second drain constitute the second thin film transistor.

According to some embodiments, the manufacturing method for an array substrate as provided by an embodiment of the present disclosure further comprises a step of: after forming the first active layer and prior to forming the second conductive layer, forming an etch barrier pattern on a surface of the first active layer away from the second insulating layer.

According to some embodiments, in the manufacturing method for an array substrate as provided by an embodiment of the present disclosure, the second conductive layer further comprises a touch signal line located in the display region. In this case, the manufacturing method further comprises: after forming the second conductive layer, forming a third insulating layer and a touch electrode successively on a surface of the second conductive layer away from the second insulating layer, wherein the touch electrode is electrically connected to the touch signal line through a via hole penetrating through the third insulating layer, and the touch electrode is also used as a common electrode.

According to some embodiments, the manufacturing method for an array substrate as provided by an embodiment of the present disclosure further comprises a step of: after forming the second conductive layer, forming a third insulating layer, a touch signal line, a fourth insulating layer, and a touch electrode successively on a surface of the second conductive layer away from the second insulating layer, wherein the touch electrode is electrically connected to the touch signal line through a via hole penetrating through the fourth insulating layer, and the touch electrode is also used as a common electrode.

According to some embodiments, the manufacturing method for an array substrate as provided by an embodiment of the present disclosure further comprises a step of: forming a data line parallel to the touch signal line in a different layer from the touch signal line, wherein an orthographic projection of the touch signal line on the base substrate and an orthographic projection of the data line on the base substrate at least partially overlap with each other.

### BRIEF DESCRIPTION OF THE DRAWINGS

In order to illustrate the technical solutions in embodiments of the present disclosure more clearly, the drawings to be used in description of the embodiments will be briefly described below. Obviously, the drawings in the description below merely represent some embodiments of the present disclosure. Other embodiments may be further obtained by those ordinarily skilled in the art based on these drawings without spending inventive efforts.

FIG. 1 is a schematic plan view showing an array substrate that comprises a display region and a non-display region according to an embodiment of the present disclosure;

FIG. 2(a) is a schematic side view showing an array substrate according to the related art;

FIG. 2(b) is a schematic plan view showing a display region of the array substrate in FIG. 2(a);

FIG. 3 is a schematic side view showing an array substrate according to an embodiment of the present disclosure;

FIG. 4(a) is a schematic side view showing an array substrate according to another embodiment of the present disclosure;

FIG. 4(b) is a schematic plan view showing a display region of the array substrate in FIG. 4(a);

FIG. 5(a) is a schematic side view showing an array substrate according to a further embodiment of the present disclosure;

FIG. 5 (b) is a schematic plan view showing a display region of the array substrate in FIG. 5 (a); and

FIG. 6 is a flow chart of a manufacturing method for an array substrate according to an embodiment of the present disclosure.

### DETAILED DESCRIPTION

The technical solutions in embodiments of the present disclosure will be clearly and completely described below in conjunction with the drawings in the embodiments of the present disclosure. It is apparent that the described embodiments merely represent a part of the embodiments of the present disclosure, rather than all of them. All other embodiments obtained by those ordinarily skilled in the art based on the embodiments of the present disclosure without spending inventive efforts fall within the protection scope of the present disclosure.

In the description below, the following reference numerals are used to refer to various components in an array substrate according to an embodiment of the present disclosure: 01—display region; 02—non-display region; 10—first thin film transistor; 101—first gate; 102—first active layer; 103—first source; 103′—source contact hole; 104—first drain; 104′—drain contact hole; 104″—contact hole between first drain and pixel electrode; 105—etch barrier pattern; 106—light blocking pattern; 20—second thin film transistor; 201—second active layer; 202—second source; 203—second drain; 204—second gate; 30—base substrate; 40—first insulating layer; 50—second insulating layer; 60—touch signal line; 60′—contact hole between touch signal line and touch electrode; 70—touch electrode; 80—third insulating layer; 801—third planarization layer; 802—third passivation layer; 90—fourth insulating layer; 100—fifth insulating layer; and 110—pixel electrode.

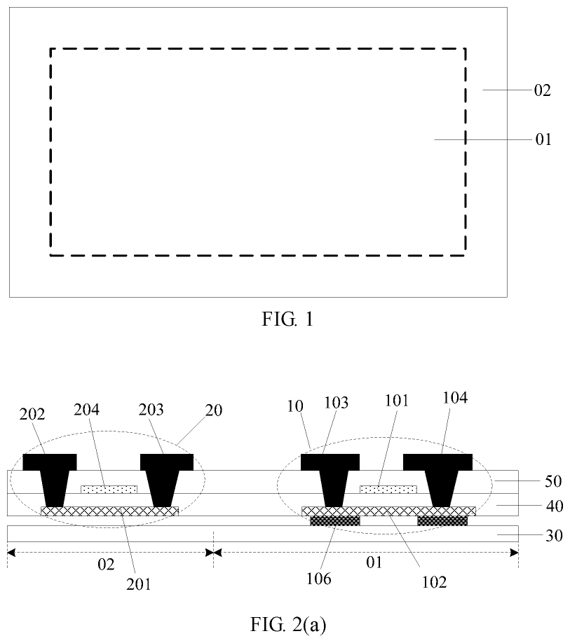

According to an embodiment of the present disclosure, an array substrate is provided. As shown in FIG. 1, the array substrate may be divided into a display region 01 and a non-display region 02. In addition, the array substrate further comprises a first thin film transistor located in the display region 01 and a second thin film transistor located in the non-display region 02, wherein the size of the second thin film transistor is smaller than that of the first thin film transistor, and the leakage current of the first thin film transistor is smaller than that of the second thin film transistor.

Here, it should be noted that the expression of “the array substrate comprises a first thin film transistor located in the display region 01” means that the display region 01 may have not only one first thin film transistor, but also a plurality of first thin film transistors. Similarly, the expression of “the array substrate comprises a second thin film transistor located in the non-display region 02” means that the non-display region 02 may have one or more second thin film transistors.

In addition, it should be noted that the first thin film transistor and the second thin film transistor may be of any suitable type, as long as it can be ensured that the size of the second thin film transistor is smaller than that of the first thin film transistor, and the leakage current of the first thin film transistor is smaller than that of the second thin film transistor. As an example, the first thin film transistor and the second thin film transistor may be bottom gate type thin film transistors, and may also be top gate type thin film transistors. In an embodiment of the present disclosure, further optionally, both the first thin film transistor and the second thin film transistor have high mobility.

Further, it should be noted that, in the array substrate provided by an embodiment of the present disclosure, in addition to the first thin film transistor and the second thin film transistor, other structures, such as pixel electrodes, data lines, gate lines, and the like, may also be included. All these structures may be formed by using the same materials and/or structures as those in the prior art and will not be enumerated herein.

Finally, it should be further noted that the second thin film transistor disposed in the non-display region 02 may function as a part of a GOA circuit, may also function as a part of a multiplexer (MUX) circuit, or may be used for other purposes. No limitation is imposed in this regard in the present disclosure.

An embodiment of the present disclosure provides an array substrate in which a first thin film transistor disposed in a display region 01 of the array substrate and a second thin film transistor disposed in a non-display region 02 of the array substrate have different types. In particular, the size and the leakage current are different between the two. Specifically, the leakage current of the first thin film transistor is smaller than that of the second thin film transistor, and the first thin film transistor is located in the display region 01. At that time, compared with the case where the second thin film transistor (which has a larger leakage current) is provided in both the display region 01 and the non-display region 02, the power consumption of the thin film transistor located in the display region 01 can be reduced. Further, in an embodiment of the present disclosure, the size of the second thin film transistor is smaller than the size of the first thin film transistor, and the second thin film transistor is located in the non-display region 02. At that time, compared with the case where the first thin film transistor (which has a larger size) is provided in both the display region 01 and the non-display region 02, the non-display region 02 can be reduced in area, thereby facilitating realization of a narrow bezel design. It can be seen that, compared with conventional technical solutions in which the same type of thin film transistors are disposed in the display region 01 and the non-display region 02, different types of thin film transistors are disposed respectively in the display region 01 and the non-display region 02 according to an embodiment of the present disclosure, which can reduce the power consumption of the display region 01 while achieving a narrow bezel design.

Optionally, in an embodiment of the present disclosure, the first thin film transistor includes a first active layer, wherein the material of the first active layer is an oxide semiconductor; and the second thin film transistor includes a second active layer, wherein the material of the second active layer is polysilicon.

Herein, when the material of the first active layer is an oxide semiconductor, the first thin film transistor is an oxide thin film transistor. When the material of the second active layer is polysilicon, the second thin film transistor is a low temperature polysilicon thin film transistor.

It should be noted that, for an oxide thin film transistor, a large size is generally selected in order to ensure high mobility of the oxide thin film transistor. However, a large size often means that the leakage current of the oxide thin film transistor is relatively small. In contrast, for a low temperature polysilicon thin film transistor, it often has a small size, which is, however, usually accompanied by a large leakage current.

In an embodiment, specific components for the oxide semiconductor may be flexibly selected as needed. As an example, the oxide semiconductor may be at least one of indium gallium zinc oxide (IGZO), indium oxide (In₂O₃), indium zinc oxide (IZO), and indium gallium zinc oxide (IGZO).

According to an embodiment of the present disclosure, the oxide thin film transistor is disposed in the display region 01. In this case, since the leakage current of the oxide thin film transistor is small, the maintenance ability of image is high. Therefore, it is not necessary to increase the refresh frequency, so that the power consumption of the display region 01 can be reduced. Further, in an embodiment of the present disclosure, the low temperature polysilicon thin film transistor is disposed in the non-display region 02. At that time, since the size of the low temperature polysilicon thin film transistor is small, the area of the non-display region 02 can be reduced, thereby satisfying the market demand for a narrow bezel product. It can be seen that, with the array substrate provided by an embodiment of the present disclosure, the power consumption of the display region 01 can be reduced while achieving a narrow bezel design.

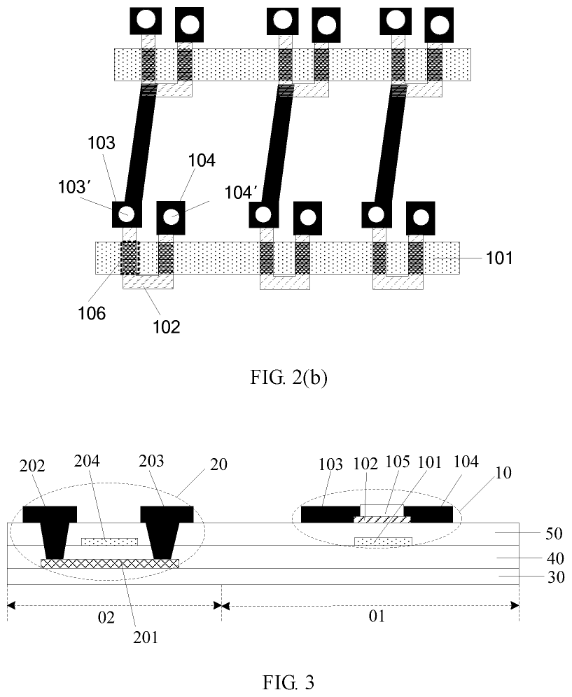

Referring to FIGS. 2(a) and 2(b) which illustrate schematic side views of an array substrate according to the related art, the array substrate comprises a first thin film transistor 10 located in a display region 01 and a second thin film transistor 20 in a non-display region 02. Generally, in the array substrate shown in FIGS. 2(a) and 2(b), the second thin film transistor 20 in the non-display region 02 and the first thin film transistor 10 in the display region 01 both have an active layer made of polysilicon. That is, in such an array substrate, both the first thin film transistor 10 and the second thin film transistor 20 are low temperature polysilicon thin film transistors. As mentioned above, the low temperature polysilicon thin film transistor has small leakage current and high power consumption, and the film of polysilicon also has poor uniformity. As a result, the array substrate as shown in FIGS. 2(a) and 2(b) has poor operability. However, in contrast, in the array substrate provided by an embodiment of the present disclosure, a first active layer 102 of the first thin film transistor 10 located in the display region 01 is made of an oxide semiconductor. In terms of the process procedure, the film of oxide semiconductor has better uniformity due to a lower temperature of the film formation process. In addition, according to the technical solutions in FIGS. 2(a) and 2(b), the first active layer 102 of the first thin film transistor 10 located in the display region 01 is made of polysilicon. Those skilled in the art should be aware that polysilicon is more sensitive to light. Therefore, in such an array substrate, it is necessary to further dispose a light blocking pattern 106 below the first active layer 102 to prevent the impact of light on polysilicon. In contrast, according to an embodiment of the present disclosure, the first active layer 102 of the first thin film transistor 10 in the display region 01 is made of an oxide semiconductor. The sensitivity of oxide semiconductor to illumination is greatly reduced as relative to polysilicon. Therefore, in the array substrate provided by an embodiment of the present disclosure, it is no longer necessary to provide the light blocking pattern 106 below the first active layer 102, which simplifies the manufacturing process for the array substrate.

According to an embodiment of the present disclosure, the second thin film transistor 20 may be fabricated in the non-display region 02 after the first thin film transistor 10 has been fabricated in the display region 01. Alternatively, the first thin film transistor 10 may be fabricated in the display region 01 after the second thin film transistor 20 has been fabricated in the non-display region 02. Of course, according to other embodiments of the present disclosure, partial film layers of the first thin film transistor 10 and the second thin film transistor 20 may also be fabricated simultaneously.

Optionally, as shown in FIG. 3, the array substrate may further comprise a second active layer 201, a first insulating layer 40, a first conductive layer, a second insulating layer 50, a first active layer 102, and a second conductive layer disposed on a base substrate 20 successively. Specifically, the first conductive layer includes a first gate 101 located in the display region 01 and a second gate 204 located in the non-display region 02. In addition, the second conductive layer includes a first source 103 and a first drain 104 located in the display region 01, and a second source 202 and a second drain 203 located in the non-display region 02. Further, as shown in FIG. 3, the first active layer 102 is kept in contact with both the first source 103 and the first drain 104. In addition, the second active layer 201 is further electrically connected to the second source 202 and the second drain 203 respectively through via holes penetrating through the first insulating layer 40 and the second insulating layer 50. In this case, the first gate 101, the second insulating layer 50, the first active layer 102, the first source 103, and the first drain 104 will constitute the first thin film transistor 10 as described above, and the second active layer 201, the first insulating layer 40, the second gate 204, the second insulating layer 50, the second source 202, and the second drain 203 will constitute the second thin film transistor 20 as described above.

As shown in FIG. 3, the first thin film transistor 10 and the second thin film transistor 20 are disposed on a base substrate 30, which are specifically located in the display region 01 and the non-display region 02 respectively.

It should be noted that, for the first thin film transistor 10, the second insulating layer 50 corresponds to a gate insulating layer (GI). For the second thin film transistor 20, the first insulating layer 40 corresponds to a gate insulating layer, and the second insulating layer 50 corresponds to an interlayer dielectric layer (ILD).

Herein, no particular requirement is imposed on the materials of the first insulating layer 40 and the second insulating layer 50 in the present disclosure. For example, the first insulating layer 40 or the second insulating layer 50 may be at least one of silicon oxide (SiOₓ), silicon nitride (SiNₓ) and silicon oxynitride (SiOₓN_{y}).

Further, FIG. 3 only schematically shows one first thin film transistor 10 disposed in the display region 01 and one second thin film transistor 20 disposed in the non-display region 02. Those skilled in the art should be able to easily conceive that a plurality of first thin film transistors 10 and a plurality of second thin film transistors may also be disposed in the display region 01 and the non-display region 02 respectively, and the present disclosure is intended to encompass all such equivalents technical solutions.

In an embodiment of the present disclosure, since the first gate 101 of the first thin film transistor 10 and the second gate 204 of the second thin film transistor 20 are formed in the same layer and of the same material, the first gate 101 and the second gate 204 may be fabricated simultaneously to simplify the manufacturing process for the array substrate. Further, since the first source 103 and the first drain 104 of the first thin film transistor 10 are formed in the same layer and of the same material as the second source 202 and the second drain 203 of the second thin film transistor 20, the first source 103 and the first drain 104 may be fabricated simultaneously with the second source 202 and the second drain 203 to simplify the manufacturing process for the array substrate. In addition, since the second insulating layer 50 can act as both the gate insulating layer of the first thin film transistor 10 and the interlayer dielectric layer of the second thin film transistor 20, the manufacturing process for the array substrate can be further simplified.

Next, referring to FIG. 2(b), it illustrates a schematic plan view of a display region of the array substrate in FIG. 2(a). As seen from FIG. 2(b), the first source 103 and the first drain 104 are in contact with the first active layer 102 through a source contact hole 103′ and a drain contact hole 104′ respectively. In contrast, according to the description in embodiments of the present disclosure, the first source 103 and the first drain 104 of the first thin film transistor 10 located in the display region 01 will be in direct contact with the first active layer 102. Compared with the conventional technical solution, this will help to omit unfavorable occupation of the opening area by metal at the via hole, thereby increasing the aperture ratio.

According to the foregoing description, in the process of forming the second conductive layer on the first active layer 102, it is necessary to form firstly a second conductive thin film on the first active layer 102, and then pattern the second conductive thin film to form the second conductive layer. At that time, the etching process used for patterning the second conductive thin film generally belongs to a dry etching process, and the dry etching process will cause damage to the first active layer 102. In view of this, in an embodiment of the present disclosure, advantageously, the array substrate may further comprise an etch barrier pattern 105 disposed on the upper surface of the first active layer 102 (i.e., a surface away from the second insulating layer 50), as shown in FIG. 3.

Here, it should be understood by those skilled in the art that in the process of disposing an etch barrier pattern 105 on the upper surface of the first active layer 102, the etch barrier pattern 105 cannot completely cover the upper surface of the first active layer 102, and some areas should be left to serve as a source contact region and a drain contact region, such that the first source 103 may be in contact with the source contact region and the first drain 104 may be in contact with the drain contact region when the first source 103 and the first drain 104 is formed continuously on the etch barrier pattern 105. It can be seen that the first source 103 and the first drain 104 in the first thin film transistor 10 are disposed on the first active layer 102 and are both in contact with the first active layer 102. On such basis, in the first active layer 102, the orthographic projection of a region other than the regions blocked by the first source 103 and the first drain 104 on the base substrate 30 at least partially overlaps with the orthographic projection of the etch barrier pattern 105 on the base substrate 30. Further optionally, in the first active layer 102, the orthographic projection of a region other than the regions blocked by the first source 103 and the first drain 104 on the base substrate 30 completely overlaps with the orthographic projection of the etch barrier pattern 105 on the base substrate 30.

In addition, as for the material used for forming the etch barrier pattern 105, it may be flexibly selected as needed, and no limitation is imposed in this regard in the present disclosure. As an example, the etch barrier pattern 105 may typically be made of SiOₓ or SiNₓ.

According to an embodiment of the present disclosure, since the etch barrier pattern 105 is formed on the upper surface of the first active layer 102, when the second conductive layer is formed on the first active layer 102, the etch barrier pattern 105 can prevent the dry etching process from causing damage to the first active layer 102, which in turn affects performances of the first active layer 102.

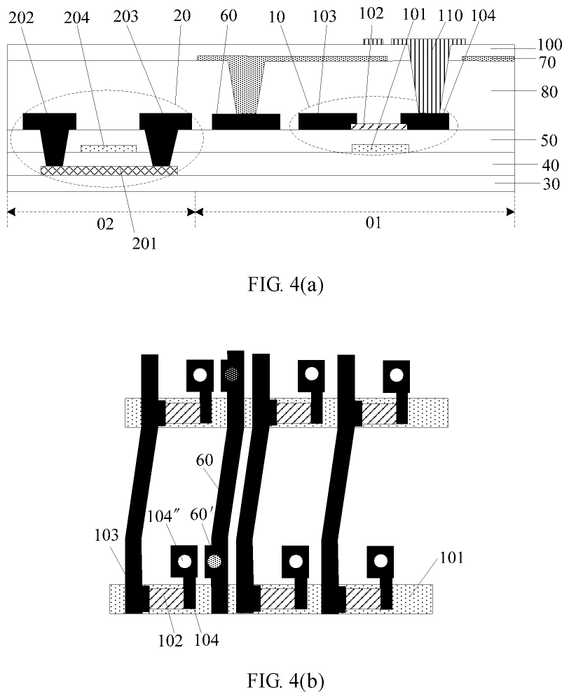

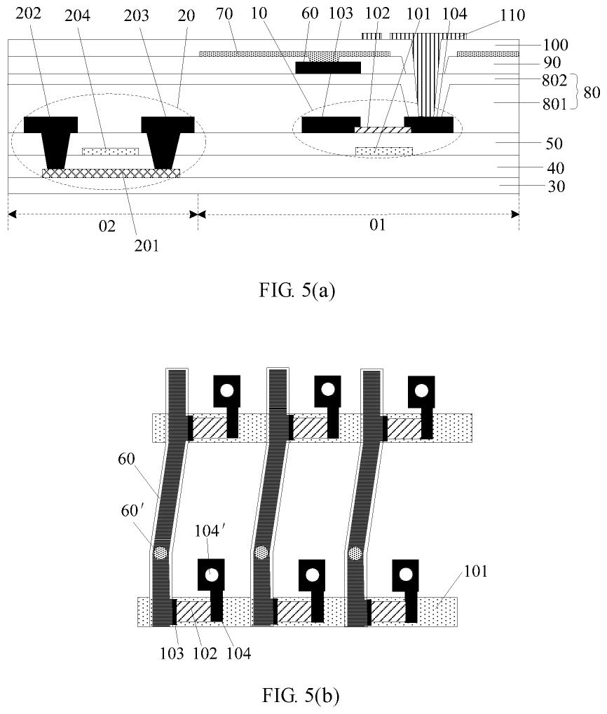

Optionally, as shown in FIG. 4(a) and FIG. 5(a), the array substrate further comprises a touch signal line 60 and a touch electrode 70 located in the display region 01, wherein the touch signal line 60 is electrically connected to the touch electrode 70, and the touch electrode 70 may be also used as a common electrode (V-com electrode).

Specifically, the touch electrode 70 may be a transparent electrode. As for the material used for forming the touch electrode 70, it may be flexibly selected as needed, and no limitation is imposed in this regard in the present disclosure. For example, the touch electrode 70 may be formed by using at least one of indium tin oxide (ITO), indium zinc oxide (IZO), and fluorine-doped tin oxide (FTO).

Herein, the expression of “the touch electrode 70 may be also used as a common electrode” means that one electrode can be used as both the touch electrode 70 and the common electrode. When the touch electrode 70 is also used as the common electrode, the touch electrode 70 and the common electrode may be time-division multiplexed.

In addition, in other embodiments, the touch signal line 60 may also be used as a common electrode line.

According to an embodiment of the present disclosure, since the touch electrode 70 is also used as the common electrode, only one electrode needs to be disposed, which functions as both the touch electrode 70 and the common electrode. This not only simplifies the manufacturing process for the array substrate, but also reduces the thickness of the array substrate.

When the array substrate comprises the touch signal line 60 and the touch electrode 70, and the touch electrode 70 is also used as the common electrode, the touch signal line 60 and the touch electrode 70 may be disposed at any suitable positions on the array substrate, and no limitation is imposed in this regard in the present disclosure. Two specific structures for the touch signal line 60 and the touch electrode 70 in the array substrate will be provided below as examples.

According to a first implementation, the touch signal line 60 is formed in the same layer and of the same material as the first source 103 and the first drain 104 of the first thin film transistor 10, as shown in FIG. 4(a) and FIG. 4(b). In addition, the array substrate further comprises a third insulating layer 80 disposed above the first thin film transistor 10, wherein the touch electrode 70 is located on the upper surface of the third insulating layer 80 and is electrically connected to the touch signal line 60 through a via hole penetrating through the third insulating layer 80.

In FIG. 4(b), a contact hole between the first drain 104 and the pixel electrode is denoted by a reference numeral 104″, and a contact hole between the touch signal line 60 and the touch electrode 70 is denoted by a reference numeral 60′.

Herein, the third insulating layer 80 is used for the purpose of planarization (PLN). That is, the third insulating layer 80 corresponds to a planarization layer, i.e., the material selected for the third insulating layer 80 should play the role of planarization.

According to an embodiment of the present disclosure, the touch signal line 60 is formed in the same layer and of the same material as the first source 103 and the first drain 104. Therefore, the touch signal line 60 may be formed while forming the first source 103 and the first drain 104, thereby simplifying the manufacturing process of the array substrate.

According to a second implementation, as shown in FIG. 5(a) and FIG. 5(b), the array substrate further comprises a third insulating layer 80 and a fourth insulating layer 90 disposed above the first thin film transistor 10 successively, wherein the touch signal line 60 is located between the third insulating layer 80 and the fourth insulating layer 90, and the touch electrode 70 is located on the upper surface of the fourth insulating layer 90 and is electrically connected to the touch signal line 60 through a via hole penetrating through the fourth insulating layer 90. Further optionally, the array substrate may further comprise a data line disposed parallel to the touch signal line 60 in a different layer, wherein the orthographic projection of the touch signal line 60 on the base substrate 30 and the orthographic projection of the data line on the base substrate 30 at least partially overlap with each other.

As an example, the third insulating layer 80 may be a single layer structure, and may also include two sub-layers. When the third insulating layer 80 includes two sub-layers, the two sub-layers may be a third planarization layer 801 and a third passivation (PVX) layer 802 respectively, which are disposed on the first thin film transistor 10 successively. Further, for example, the fourth insulating layer 90 may be used for planarization. That is, the fourth insulating layer 90 corresponds to a planarization layer.

Here, as an example, the data line may be formed simultaneously with the first source 103 and the first drain 104.

According to an embodiment of the present disclosure, when the touch signal line 60 is formed in the same layer as the first source 103 and the first drain 104, it is necessary to precisely control the spacing between the touch signal line 60 and the data line in the process. If the spacing between the touch signal line 60 and the data line is too small, the touch signal line 60 is likely to come into contact with the data line. In contrast, if the spacing between the touch signal line 60 and the data line is too large, the aperture ratio of the entire device will be reduced. In an embodiment of the present disclosure, by disposing the touch signal line 60 and the data line in different layers, it can be ensured that there is no need to take into account the technological limits of the etching conditions for metals in the same layer. In addition, by comparing FIG. 4(b) with FIG. 5(b), it can be seen that, compared with the case where the touch signal line 60 and the data line are disposed in the same layer, in embodiments of the present disclosure, the touch signal line 60 and the data line are disposed in different layers, and it is ensured that the touch signal line 60 and the data line have overlapping regions (i.e., the orthographic projections thereof at least partially overlap with each other) along the thickness direction of the array substrate. This can reduce unfavorable occupation of the opening area by the touch signal line 60, thereby greatly increasing the aperture ratio of the product.

Based on the above description, in an embodiment of the present disclosure, a buffer layer may be formed firstly on the base substrate 30 prior to forming the first thin film transistor 10 and the second thin film transistor 20 on the base substrate 30. The buffer layer can not only planarize the base substrate 30 to shield deficiencies in the base substrate 30, but also prevent impurity ions from penetrating into the base substrate 30 to cause various defects in the device. The buffer layer is not illustrated in the drawings of embodiments of the present disclosure.

Further, referring to FIG. 4 (a) and FIG. 5 (a), the array substrate may further comprise a fifth insulating layer 100 and a pixel electrode 110 disposed on the touch electrode 70 (which is also used as a common electrode) successively, wherein the pixel electrode 110 is electrically connected to the first drain 104 through a via hole. At that time, as an example, the fifth insulating layer 100 may act as a passivation layer.

According to another aspect of the present disclosure, an embodiment further provides a display device comprising the array substrate as described in any of the foregoing embodiments.

Here, the display device may be a liquid crystal display (LCD) or an organic electroluminescent display (OLED). When the display device is a liquid crystal display device, the display device may further comprise a color filter substrate in addition to the array substrate. When the display device is an organic electroluminescent display device, in addition to the array substrate, the display device further comprises a package substrate or a package film that can be used to package the array substrate. In addition, the display device provided by an embodiment of the present disclosure may also be a display panel.

Additionally, as an example, the display device provided by an embodiment of the present disclosure may be any device for displaying moving images (e.g., videos) and/or stationary images (e.g., still images). Alternatively, the display device provided by an embodiment of the present disclosure may also be any device for displaying textual and/or graphic images. More specifically, it is contemplated that the described embodiment may be implemented in various electronic devices or associated with various electronic devices. The various electronic devices include (but are not limited to), for example, mobile phones, wireless devices, personal data assistants (PDAs), handheld or portable computers, GPS receivers/navigators, cameras, MP4 video players, video cameras, game consoles, watches, clocks, calculators, television monitors, flat panel displays, computer monitors, car displays (e.g., odometer displays, etc.), navigators, cockpit controllers and/or displays, camera view displays (e.g., rear view camera displays in vehicles), electronic photos, electronic billboards or signage, projectors, building structures, package and aesthetic structures (e.g., a display for an image of a piece of jewelry), and the like.

An embodiment of the present disclosure provides a display device. The display device comprises an array substrate according to any of the foregoing embodiments. The array substrate in such a display device has the same structure and beneficial effects as the array substrate provided in the foregoing embodiments. Since the structure and the beneficial effects of the array substrate have been described in detail in the foregoing embodiments, they are not described herein again.

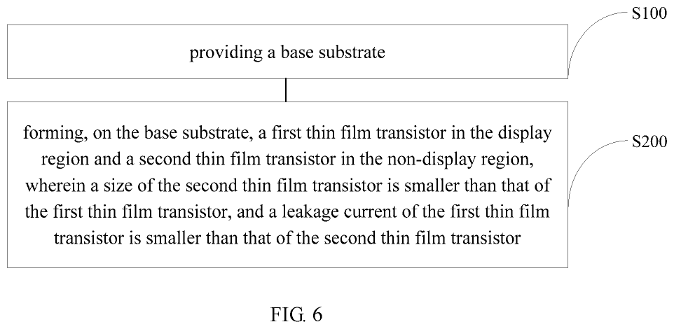

According to a further aspect of the present disclosure, an embodiment further provides a manufacturing method for an array substrate. As shown in FIG. 6, the manufacturing method comprises the steps of: S100, providing a base substrate 30, wherein the base substrate 30 includes a display region 01 and a non-display region 02; and S200, forming, on the base substrate 30, a first thin film transistor 10 located in the display region 01 and a second thin film transistor 20 located in the non-display region 02, wherein the size of the second thin film transistor 20 is smaller than that of the first thin film transistor 10, and the leakage current of the first thin film transistor 10 is smaller than that of the second thin film transistor 20.

Here, the first thin film transistor 10 and the second thin film transistor 20 may be of any suitable type, as long as it can be ensured that the size of the second thin film transistor 20 is smaller than that of the first thin film transistor 10 and the leakage current of the first thin film transistor 10 is smaller than that of the second thin film transistor 20. As an example, the first thin film transistor 10 and the second thin film transistor 20 may be bottom gate type thin film transistors, and may also be top gate type thin film transistors. In an embodiment of the present disclosure, optionally, the first thin film transistor 10 and the second thin film transistor 20 both have high mobility.

In addition, the second thin film transistor 20 disposed in the non-display region 02 may function as a part of a GOA circuit, may also function as a part of an MUX circuit, or may be used for other purposes, and no limitation is imposed in this regard in the present disclosure.

An embodiment of the present disclosure provides a manufacturing method for an array substrate. The manufacturing method for an array substrate has the same characteristics and beneficial effects as the array substrate provided by the foregoing embodiments. Since the structure and the beneficial effects of the array substrate have been described in detail in the foregoing embodiments, they are not described herein again.

Optionally, in an embodiment of the present disclosure, the first thin film transistor 10 includes a first active layer 102, wherein the material of the first active layer 102 is an oxide semiconductor; and the second thin film transistor 20 includes a second active layer 201, wherein the material of the second active layer 201 is polysilicon.

Here, when the material of the first active layer 102 is an oxide semiconductor, the first thin film transistor 10 is an oxide thin film transistor; and when the material of the second active layer 201 is polysilicon, the second thin film transistor 20 is a low temperature polysilicon thin film transistor.

According to an embodiment of the present disclosure, the first thin film transistor 10 is formed in the display region 01, and the first thin film transistor 10 is selected as an oxide thin film transistor. In this case, since the leakage current of the oxide thin film transistor is small, the maintenance ability of image is high. Therefore, it is not necessary to increase the refresh frequency, so that the power consumption of the display region 01 can be reduced. Further, according to an embodiment of the present disclosure, the second thin film transistor 20 is formed in the non-display region 02, and the second thin film transistor 20 is selected as a polysilicon thin film transistor. At that time, since the size of the low temperature polysilicon thin film transistor is small, the area of the non-display region 02 can be reduced, thereby satisfying the market demand for a narrow bezel product. It can be seen that, with the manufacturing method for an array substrate provided by an embodiment of the present disclosure, the power consumption of the display region 01 can be reduced while achieving a narrow bezel design. In addition, in implementations of the present disclosure, the first active layer 102 located in the display region 01 is formed using an oxide semiconductor. In this manner, in terms of the process procedure, since the film formation process for the oxide semiconductor has a lower temperature, the film uniformity is better.

Optionally, in an embodiment of the present disclosure, step S200 may include the sub-steps of: forming, on the base substrate 30, a second active layer 201, a first insulating layer 40, a first conductive layer, a second insulating layer 50, a first active layer 102 and a second conductive layer successively. As shown in FIG. 3, the first conductive layer includes a first gate 101 located in the display region 01 and a second gate 204 located in the non-display region 02; the second conductive layer includes a first source 103 and a first drain 104 located in the display region 01, and a second source 202 and a second drain 203 located in the non-display region 02; the first active layer 102 is in contact with both the first source 103 and the first drain 104; and the second active layer 201 is electrically connected to the second source 202 and the second drain 203 through via holes penetrating through the first insulating layer 40 and the second insulating layer 50. In this case, the first gate 101, the second insulating layer 50, the first active layer 102, the first source 103, and the first drain 104 will constitute the first thin film transistor 10; and the second active layer 201, the first insulating layer 40, the second gate 204, the second insulating layer 50, the second source 202, and the second drain 203 will constitute the second thin film transistor 20.

It should be noted that, for the first thin film transistor 10, the second insulating layer 50 corresponds to a gate insulating layer. For the second thin film transistor 20, the first insulating layer 40 corresponds to a gate insulating layer, and the second insulating layer 50 corresponds to an interlayer dielectric layer.

According to an embodiment of the present disclosure, the first gate 101 of the first thin film transistor 10 and the second gate 204 of the second thin film transistor 20 are fabricated simultaneously, which can simplify the manufacturing process for the array substrate. In addition, the first source 103 and the first drain 104 of the first thin film transistor 10 may be fabricated simultaneously with the second source 202 and the second drain 203 of the second thin film transistor 20, which can simplify the manufacturing process for the array substrate. Further, the second insulating layer 50 can serve as both the gate insulating layer of the first thin film transistor 10 and the interlayer dielectric layer of the second thin film transistor 20, which can simplify further the manufacturing process for the array substrate.

Referring back to FIG. 2(b), it illustrates a schematic plan view of a display region of the array substrate in FIG. 2(a). As seen from FIG. 2(b), the first source 103 and the first drain 104 are in contact with the first active layer 102 through the source contact hole 103′ and the drain contact hole 104′ respectively. In contrast, according to the description in embodiments of the present disclosure, the first source 103 and the first drain 104 of the first thin film transistor 10 located in the display region 01 will be in direct contact with the first active layer 102. Compared with the conventional technical solution, this will help to omit unfavorable occupation of the opening area by metal at the via hole, thereby increasing the aperture ratio.

Optionally, in an embodiment of the present disclosure, the manufacturing method for an array substrate may further comprise: after forming the first active layer 102 on the base substrate 30 and prior to forming the second conductive layer, forming an etch barrier pattern 105 on the upper surface of the first active layer 102.

For the material forming the etch barrier pattern 105, it may be flexibly selected as needed, and no limitation is imposed in this regard in the present disclosure. As an example, the etch barrier pattern 105 may typically be made of SiOₓ or SiNₓ.

According to an embodiment of the present disclosure, since the etch barrier layer 105 is formed on the upper surface of the first active layer 102, when the second conductive layer is formed on the first active layer 102, the etch barrier pattern 105 can prevent the dry etching process from causing damage to the first active layer 102, which in turn affects performances of the first active layer 102.

Optionally, as shown in FIG. 4(a), the second conductive layer further includes a touch signal line 60 located in the display region 01. In this case, the manufacturing method for an array substrate may further comprise: after forming the second conductive layer, forming a third insulating layer 80 and a touch electrode 70 on the second conductive layer successively, wherein the touch electrode 70 is electrically connected to the touch signal line 60 through a via hole penetrating through the third insulating layer 80, and the touch electrode 70 is also used as a common electrode.

Further optionally, the touch signal line 60 may also be used as a common electrode line.

Here, the expression of “the touch electrode 70 may be also used as a common electrode” means that one electrode can be used as both the touch electrode 70 and the common electrode. When the touch electrode 70 is also used as the common electrode, the touch electrode 70 and the common electrode may be time-division multiplexed.

According to an embodiment of the present disclosure, since the touch electrode 70 is also used as the common electrode, only one electrode needs to be disposed, which functions as both the touch electrode 70 and the common electrode. This not only simplifies the manufacturing process for the array substrate, but also reduces the thickness of the array substrate. In addition, the touch signal line 60 may be fabricated simultaneously with the first source 103 and the first drain 104, which is advantageous for simplifying the manufacturing process for the array substrate.

Optionally, as shown in FIG. 5(a), the manufacturing method for an array substrate may further comprise the step of: after forming the second conductive layer, forming a third insulating layer 80, a touch signal line 60, a fourth insulating layer 90 and a touch electrode 70 on the second conductive layer successively, wherein the touch electrode 70 is electrically connected to the touch signal line 60 through a via hole penetrating through the fourth insulating layer 90, and the touch electrode 70 is also used as a common electrode. Further optionally, the manufacturing method for an array substrate may further comprise the step of: forming a data line parallel to the touch signal line 60 in a different layer, wherein the orthographic projection of the touch signal lines 60 on the base substrate 30 and that of the data line on the base substrate 30 at least partially overlap with each other.

Here, as an example, the data line may be formed simultaneously with the first source 103 and the first drain 104.

According to an embodiment of the present disclosure, when the touch signal line 60 is formed in the same layer as the first source 103 and the first drain 104, it is necessary to precisely control the spacing between the touch signal line 60 and the data line in the process. If the spacing between the touch signal line 60 and the data line is too small, the touch signal line 60 is likely to come into contact with the data line. In contrast, if the spacing between the touch signal line 60 and the data line is too large, the aperture ratio of the entire device will be reduced. In embodiments of the present disclosure, by disposing the touch signal line 60 and the data line in different layers, it can be ensured that there is no need to take into account the technological limits of the etching conditions for metals in the same layer. In addition, compared with the case where the touch signal line 60 and the data line are disposed in the same layer, the touch signal line 60 and the data line have overlapping regions (i.e., the orthographic projections thereof at least partially overlap with each other) along the thickness direction of the array substrate, which can reduce unfavorable occupation of the opening area by the touch signal line 60, thereby greatly increasing the aperture ratio of the product.

What have been stated above are only specific embodiments of the present disclosure, but the protection scope of the present disclosure is not so limited. Any variations or substitutions that can be easily conceived by the skilled persons familiar with this technical field within the technical scope revealed by the present disclosure shall be encompassed within the protection scope of the present disclosure. Thus, the protection scope of the present disclosure should be based on the scope of the claims.

1. An array substrate comprising:
a display region; and
a non-display region,
wherein the array substrate further comprises a first thin film transistor in the display region and a second thin film transistor in the non-display region,
wherein a second size of the second thin film transistor is smaller than a first size of the first thin film transistor, and a first leakage current of the first thin film transistor is smaller than a second leakage current of the second thin film transistor.

2. The array substrate according to claim 1,
wherein the first thin film transistor comprises a first active layer comprising an oxide semiconductor, and
wherein the second thin film transistor comprises a second active layer comprising polysilicon.

3. The array substrate according to claim 1, further comprising:
a base substrate; and
a second active layer, a first insulating layer, a first conductive layer, a second insulating layer, a first active layer and a second conductive layer on the base substrate successively,
wherein the first conductive layer comprises a first gate in the display region and a second gate in the non-display region,
wherein the second conductive layer comprises a first source and a first drain in the display region, and a second source and a second drain in the non-display region,
wherein the first active layer is in contact with both the first source and the first drain,
wherein the second active layer is electrically connected to the second source and the second drain through via holes penetrating through the first insulating layer and the second insulating layer,
wherein the first gate, the second insulating layer, the first active layer, the first source and the first drain comprise the first thin film transistor, and
wherein the second active layer, the first insulating layer, the second gate, the second insulating layer, the second source and the second drain comprise the second thin film transistor.

4. The array substrate according to claim 3, further comprising:
an etch barrier pattern on a surface of the first active layer away from the second insulating layer.

5. The array substrate according to claim 3, further comprising:
a touch signal line and a touch electrode in the display region,
wherein the touch signal line is electrically connected to the touch electrode, and
wherein the touch electrode is used as a common electrode.

6. The array substrate according to claim 5,
wherein the touch signal line is in a same layer and comprises a same material as the first source and the first drain of the first thin film transistor,
wherein the array substrate further comprises a third insulating layer on a surface of the first thin film transistor away from the second insulating layer,
wherein the touch electrode is on a surface of the third insulating layer away from the first thin film transistor, and is electrically connected to the touch signal line through a via hole penetrating through the third insulating layer.

7. The array substrate according to claim 3, further comprising:
a third insulating layer and a fourth insulating layer stacked successively on a surface of the first thin film transistor away from the second insulating layer,
wherein the touch signal line is between the third insulating layer and the fourth insulating layer, and
wherein the touch electrode is on a surface of the fourth insulating layer away from the third insulating layer, and is electrically connected to the touch signal line through a via hole penetrating through the fourth insulating layer.

8. The array substrate according to claim 6, further comprising:
a data line in a different layer from the touch signal line and parallel to the touch signal line,
wherein an orthographic projection of the touch signal line on the base substrate at least partially overlaps with an orthographic projection of the data line on the base substrate.

9. A display device comprising the array substrate according to claim 1.

10. A manufacturing method for an array substrate, comprising:
providing a base substrate comprising a display region and a non-display region; and
forming, on the base substrate, a first thin film transistor in the display region and a second thin film transistor in the non-display region,
wherein a second size of the second thin film transistor is smaller than a first size of the first thin film transistor, and a first leakage current of the first thin film transistor is smaller than a second leakage current of the second thin film transistor.

11. The manufacturing method according to claim 10,
wherein the first thin film transistor comprises a first active layer comprising an oxide semiconductor, and
wherein the second thin film transistor comprises a second active layer comprising polysilicon.

12. The manufacturing method according to claim 10, wherein the forming the first thin film transistor in the display region and the second thin film transistor in the non-display region comprises:
forming, on the base substrate, a second active layer, a first insulating layer, a first conductive layer, a second insulating layer, a first active layer and a second conductive layer successively,
wherein the first conductive layer comprises a first gate in the display region and a second gate in the non-display region,
wherein the second conductive layer comprises a first source and a first drain in the display region, and a second source and a second drain in the non-display region,
wherein the first active layer is in contact with both the first source and the first drain,
wherein the second active layer is electrically connected to the second source and the second drain through via holes penetrating through the first insulating layer and the second insulating layer,
wherein the first gate, the second insulating layer, the first active layer, the first source and the first drain comprise the first thin film transistor, and
wherein the second active layer, the first insulating layer, the second gate, the second insulating layer, the second source and the second drain comprise the second thin film transistor.

13. The manufacturing method according to claim 12, further comprising:
after forming the first active layer and prior to forming the second conductive layer, forming an etch barrier pattern on a surface of the first active layer away from the second insulating layer.

14. The manufacturing method according to claim 12, wherein the second conductive layer further comprises a touch signal line in the display region, and the manufacturing method further comprising:
after forming the second conductive layer, forming a third insulating layer and a touch electrode successively on a surface of the second conductive layer away from the second insulating layer,
wherein the touch electrode is electrically connected to the touch signal line through a via hole penetrating through the third insulating layer, and
wherein the touch electrode is used as a common electrode.

15. The manufacturing method according to claim 12, further comprising:
after forming the second conductive layer, forming a third insulating layer, a touch signal line, a fourth insulating layer and a touch electrode successively on a surface of the second conductive layer away from the second insulating layer,
wherein the touch electrode is electrically connected to the touch signal line through a via hole penetrating through the fourth insulating layer, and the touch electrode is used as a common electrode.

16. The manufacturing method according to claim 14, further comprising:
forming a data line parallel to the touch signal line in a different layer from the touch signal line,
wherein an orthographic projection of the touch signal line on the base substrate at least partially overlaps with an orthographic projection of the data line on the base substrate.

17. The array substrate according to claim 7, further comprising:
a data line in a different layer from the touch signal line and parallel to the touch signal line,
wherein an orthographic projection of the touch signal line on the base substrate at least partially overlaps with an orthographic projection of the data line on the base substrate.

18. The manufacturing method according to claim 15, further comprising:
forming a data line parallel to the touch signal line in a different layer from the touch signal line,
wherein an orthographic projection of the touch signal line on the base substrate at least partially overlaps with an orthographic projection of the data line on the base substrate.

19. The display device according to claim 9,
wherein the first thin film transistor comprises a first active layer,
wherein the material of the first active layer comprises oxide semiconductor,
wherein the second thin film transistor comprises a second active layer, and
wherein the material of the second active layer comprises polysilicon.

20. The display device according to claim 9, wherein the array substrate further comprises:
a base substrate; and
a second active layer, a first insulating layer, a first conductive layer, a second insulating layer, a first active layer and a second conductive layer disposed on the base substrate successively,
wherein the first conductive layer comprises a first gate in the display region and a second gate in the non-display region,
wherein the second conductive layer comprises a first source and a first drain in the display region, and a second source and a second drain in the non-display region;
wherein the first active layer is in contact with both the first source and the first drain; and
wherein the second active layer is electrically connected to the second source and the second drain through via holes penetrating through the first insulating layer and the second insulating layer,
wherein the first gate, the second insulating layer, the first active layer, the first source and the first drain comprise the first thin film transistor, and
wherein the second active layer, the first insulating layer, the second gate, the second insulating layer, the second source and the second drain comprise the second thin film transistor.
